(19) United States
(12) Patent Application Publication
(10) Pub. No.: US 2024/0222099 A1
(43) Pub. Date: Jul. 4, 2024

(54) CONTROL METHOD FOR SUPPORT UNIT, SUBSTRATE TREATING METHOD AND SUBSTRATE TREATING APPARATUS

(71) Applicant: SEMES CO., LTD., Cheonan-si (KR)

(72) Inventors: Yun Sik JU, Yongin-si (KR); Chung Woo LEE, Suwon-si (KR)

(73) Assignee: SEMES CO., LTD., Cheonan-si (KR)

(21) Appl. No.: 18/541,437

(22) Filed: Dec. 15, 2023

(30) Foreign Application Priority Data
Dec. 30, 2022 (KR) 10-2022-0190518

(51) Int. Cl. H01J 37/32; H01L 21/683

(52) U.S. Cl. CPC H01J 37/32935; H01J 37/32724; H01L 21/6833; H01J 2237/24564; H01J 2237/24585

(57) ABSTRACT

The inventive concept provides a control method for controlling a support unit. The support unit includes a support plate on which a substrate is placed; a first heater installed on the support plate; and a second heater installed on the support plate at a different height from the first heater, and the control method includes: determining whether a temperature of the first heater has reached a normal state after the temperature of the first heater varies; measuring a resistance of the second heater after the temperature of the first heater has reached the normal state; and calculating a compensation factor for estimating a temperature of the second heater based on the resistance of the second heater which has been measured.

### CROSS-REFERENCE TO RELATED APPLICATIONS

A claim for priority under 35 U.S.C. § 119 is made to Korean Patent Application No. 10-2022-0190518 filed on Dec. 30, 2022, in the Korean Intellectual Property Office, the entire contents of which are hereby incorporated by reference.

### BACKGROUND

Embodiments of the inventive concept described herein relate to a control method for a support unit, a substrate treating method, and a substrate treating apparatus.

A plasma refers to an ionized gas state consisting of ions, radicals, and electrons, and is produced by very high temperatures, strong electric fields, or high-frequency electronic fields (RF Electromagnetic Fields). A semiconductor element manufacturing process performs various processes using the plasma. For example, the semiconductor element manufacturing process may include an etching process of removing a thin film on a substrate using the plasma, or a deposition process of depositing a film on the substrate using the plasma.

A plasma substrate treating apparatus which uses the plasma to process a substrate such as a wafer requires an accuracy to precisely perform a substrate treatment, a repetitive reproducibility to constantly treat between substrates even if a plurality of substrates are treated, and a uniformity to uniformly treat throughout an entire region of a single substrate.

Meanwhile, an electrostatic chuck (ESC) which supports the substrate can heat the substrate while treating the substrate using the plasma. In order to ensure the uniformity, a temperature of each region of the substrate must be uniform while the substrate treatment is performed. During the substrate treatment, it is necessary to precisely control the temperature of each region of the substrate in order to maintain a uniform temperature at each region of the substrate. For this reason, a plurality of heaters capable of controlling the temperature of each region of the substrate are installed in the electrostatic chuck. An output of each heater may be independently controlled.

FIG. 1 is a flowchart schematically illustrating a general method of controlling an output of a heater.

Referring to FIG. 1, an output control of the heater is generally controlled by a closed-loop system. More specifically, a temperature of a heater installed on the electrostatic chuck is measured in step S1, whether the temperature of the heater measured in step S2 is within a tolerance is determined, and if it is within the tolerance, the output control of the heater is terminated in step S3, and if it is out of the tolerance, the output of the heater is changed in step S4 to correct the temperature of the heater. This control method may be called a feedback control.

In order to implement the closed-loop system as described above, it is necessary to measure the temperature of the heater. In order to measure the temperature of the heater, a temperature measurement sensor capable of measuring the temperature of the heater must be installed in the electrostatic chuck.

Recently, the number of heaters installed in the electrostatic chuck is increasing to more accurately control the temperature of each region of the substrate. Therefore, in order to implement the closed-loop system as described above, a large number of temperature measurement sensors will have to be installed in the electrostatic chuck. However, due to a structure of the electrostatic chuck, it is very difficult to install a large number of temperature measurement sensors in the electrostatic chuck, and even if an installation is possible, it is not appropriate because it makes the structure of the electrostatic chuck very complicated.

For this reason, if the number of heaters installed on the electrostatic chuck exceeds a certain number, the temperature of the heater is controlled by applying an open-loop system rather than a closed-loop system. If the open-loop system is applied, the temperature of the heater is not fed back. Accordingly, the above-described temperature measurement sensor is not required.

Since the open-loop system does not feedback the temperature of the heater, the open-loop system must accurately preset how much the output of the heater should be during a process through experiments. In order to calculate a set point for the output of the heater, generally a wafer-type sensor having a same or similar shape as the substrate is introduced into a substrate treating apparatus which performs a plasma process, and the wafer-type sensor measures a temperature distribution on a electrostatic chuck surface in the same environment as the actual process conditions. Based on a measured data, a temperature distribution change of the electrostatic chuck surface is confirmed, and the output of the heater required for the process is calculated.

However, this method requires a separate wafer-type sensor. In addition, the wafer-type sensor should be taken into the substrate treating apparatus to calculate a data, the temperature distribution change of the electrostatic chuck surface should be confirmed from a calculated data, and based on the measured data the output of the heater should be calculated. In addition, the above three steps have to be carried out by an operator repeatedly until the temperature distribution of the electrostatic chuck surface reaches a target point. In addition, there is an additional cost for using a separate wafer-type sensor.

### SUMMARY

Embodiments of the inventive concept provide a control method of a support unit, a substrate treating method, and a substrate treating apparatus for efficiently treating a substrate.

Embodiments of the inventive concept provide a control method of a support unit, a substrate treating method, and a substrate treating apparatus for improving a treatment uniformness with respect to a substrate.

Embodiments of the inventive concept provide a control method of a support unit, a substrate treating method, and a substrate treating apparatus for controlling a temperature of a heater while considering a minute temperature different which can occur between heaters due to an influence of an installation position of the heaters, surrounding structures, or the like.

The technical objectives of the inventive concept are not limited to the above-mentioned ones, and the other unmentioned technical objects will become apparent to those skilled in the art from the following description.

The inventive concept provides a control method for controlling a support unit including a support plate on which a substrate is placed; a first heater installed on the support plate; and a second heater installed on the support plate at a different height from the first heater. The control method includes determining whether a temperature of the first heater has reached a normal state after the temperature of the first heater varies; measuring a resistance of the second heater after the temperature of the first heater has reached the normal state; and calculating a compensation factor for estimating a temperature of the second heater based on the resistance of the second heater which has been measured.

In an embodiment, the compensation factor is a in the below equation. [Equation] Tf=T0+(Rf−R0)/α (Tf: Estimation temperature of the second heater, T0: Initial temperature of the second heater, Rf: Measurement resistance of the second heater, R0: Initial resistance of the second heater)

In an embodiment, the temperature of the first heater which has reached the normal state is assumed as the estimation temperature (Tf) of the second heater, and the measurement resistance (Rf) of the second heater is measured after reaching the normal state to calculate the compensation factor.

In an embodiment, if a change of a measurement value of a temperature measurement sensor which measures the temperature of the first heater is within a set range after the temperature of the first heater varies, or if a set time elapses after the temperature of the first heater varies, it is determined that the normal state has been reached.

In an embodiment, a first compensation factor is calculated which is the compensation factor corresponding to the first temperature of the first heater after the first heater varies to the first temperature, and a second compensation factor is calculated which is the compensation factor corresponding to a second temperature of the first heater after the first heater varies to the second temperature which is different from the first temperature.

In an embodiment, if the temperature of the first heater is adjusted to the first temperature, the resistance of the second heater is measured, and the temperature of the second heater is estimated based on a measured resistance and the first compensation factor, and if the temperature of the second heater is adjusted to the second temperature, the resistance of the second heater is measured, and the temperature of the second heater is estimated based on a measured resistance and the second compensation factor.

In an embodiment, the temperature of the second heater is estimated using a measurement resistance of the second heater and the compensation factor, and an output of the second heater is adjusted using the temperature of the temperature of the second heater which is estimated.

The inventive concept provides a substrate treating method using a first heater and a second heater installed at a position which is different from the first heater. The substrate treating method includes collecting a data with respect to a measured resistance of the second heater according to each temperature of the first heater by measuring a resistance of the second heater, after a temperature of the first heater varies, and the temperature of the first heater reaches a normal state; calculating a compensation factor for estimating a temperature of the second heater according to the measured resistance of the second heater, based on the measurement resistance of the second heater, an initial temperature of the second heater, and an initial resistance of the second heater; treating a substrate by estimating the temperature of the second heater using the compensation factor, and controlling an output of the second heater based on the temperature of the second heater which is estimated.

In an embodiment, the compensation factor is calculated for each temperature of the first heater which changes at the treating the substrate.

In an embodiment, the compensation factor is a in the below equation. [Equation] Tf=T0+(Rf−R0)/α (Tf: Estimation temperature of the second heater, T0: Initial temperature of the second heater, Rf: Measurement resistance of the second heater, R0: Initial resistance of the second heater)

In an embodiment, the calculating the compensation factor includes: assuming the temperature of the first heater which has reached the normal state to be an estimation temperature (Tf) of the second heater; selecting the measurement resistance of the second heater corresponding to the estimation temperature (Tf) which is assumed collected at the collecting the data; and calculating the compensation factor (α) by substituting the measurement resistance (Rf) which is selected, the estimation temperature (Tf) which is assumed, the initial temperature (T0) of the second heater which is stored in advance, and the initial resistance (R0) of the second heater which is stored in advance.

In an embodiment, at the treating the substrate, if an estimation temperature of the second heater which is estimated at the treating the substrate is different from a set temperature which is targeted, an output of the second heater is adjusted so the estimation temperature of the second heater reaches the set temperature.

In an embodiment, at the collecting the data, it is determined that the normal state is reached if a change of a measurement value of a temperature measurement sensor which measures the temperature of the first heater is within a set range after the temperature of the first heater varies or if a set time elapses after the temperature of the first heater varies.

In an embodiment, the collecting the data and the calculating the compensation factor is performed if a substrate treating apparatus which performs the substrate treating method is set up or if the substrate treating apparatus is redriven.

The inventive concept provides a substrate treating apparatus. The substrate treating apparatus includes a chamber providing a treating space for performing a substrate treatment process within; a support unit configured to support a substrate in the treating space; a high frequency power source for generating a plasma in the treating space; and a main controller, and wherein the support unit includes: a support plate on which the substrate is placed; a first heater which is installed on the support plate; a first controller which controls on output of the first heater; a second heater which is installed on the support plate at a height different from the first heater and which has a heating area smaller than the first heater; a second controller for controlling an output of the second heater; a temperature measurement sensor for measuring a temperature of the first heater and a resistance measurement sensor for measuring a resistance of the second heater, and wherein the main controller: controls the first controller so the temperature of the first heater varies, controls the resistance measurement sensor to measure the resistance of the second heater after the temperature of the first heater reaches a normal state, calculates a compensation factor for estimating a temperature of the second heater based on a measurement resistance of the second heater measured by the resistance measurement sensor using the measurement resistance of the second heater which is measured and the temperature of the first heater which has reached the normal state, and controls the second controller to change the temperature of the second heater based on the compensation factor which is calculated.

In an embodiment, the main controller prestores an initial resistance and an initial temperature of the second heater; and calculates the compensation factor using the initial resistance of the second heater, the initial temperature of the second heater, and the measurement resistance of the second heater and the temperature of the first heater which has reached the normal state.

In an embodiment, the first heater and the second heater are installed in a plurality, and the number of second heater is higher than the number of the first heater.

In an embodiment, the second heater is installed above the first heater.

In an embodiment, the temperature measurement sensor is a fiber optic sensor for measuring the temperature of the first heater by irradiating a light to the first heater installed on the support plate, and the resistance measurement sensor is installed outside of the support plate.

In an embodiment, the main controller calculates each compensation factor per temperature of the first heater for each second heater.

According to an embodiment of the inventive concept, a substrate can be efficiently treated.

According to an embodiment of the inventive concept, a treatment uniformness with respect to a substrate may be improved.

According to an embodiment of the inventive concept, a temperature of a heater can be controlled while considering a minute temperature difference of heaters which can occur due to an influence of an installation position of heaters, a surrounding structure, or the like.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a flowchart schematically illustrating a general method of controlling an output of a heater.

FIG. 2 is a cross-sectional view illustrating a substrate treating apparatus according to an embodiment of the inventive concept.

FIG. 3 is an explanatory view schematically illustrating an arrangement of a first heater of FIG. 2.

FIG. 4 is an explanatory view schematically illustrating an arrangement of a second heater of FIG. 2.

FIG. 5 is an explanatory view schematically illustrating a method of controlling an output of the first heater by a first heater module.

FIG. 6 is an explanatory view schematically illustrating a method of controlling an output of the second heater by a second heater module.

FIG. 7 is a flowchart illustrating a method of controlling a support unit according to an embodiment of the inventive concept.

FIG. 8 is a graph schematically illustrating a resistance change according to a temperature change of the second heater.

FIG. 9 is a flowchart illustrating a substrate treating method according to an embodiment of the inventive concept.

FIG. 10 is a flowchart illustrating the substrate treating method according to another embodiment of the inventive concept.

FIG. 11 is a cross-sectional view illustrating the substrate treating apparatus according to another embodiment of the inventive concept.

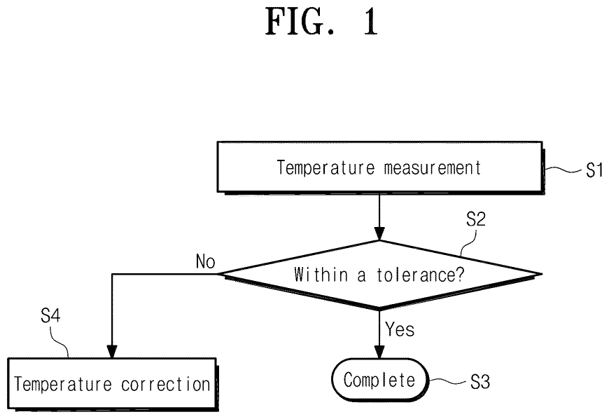

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

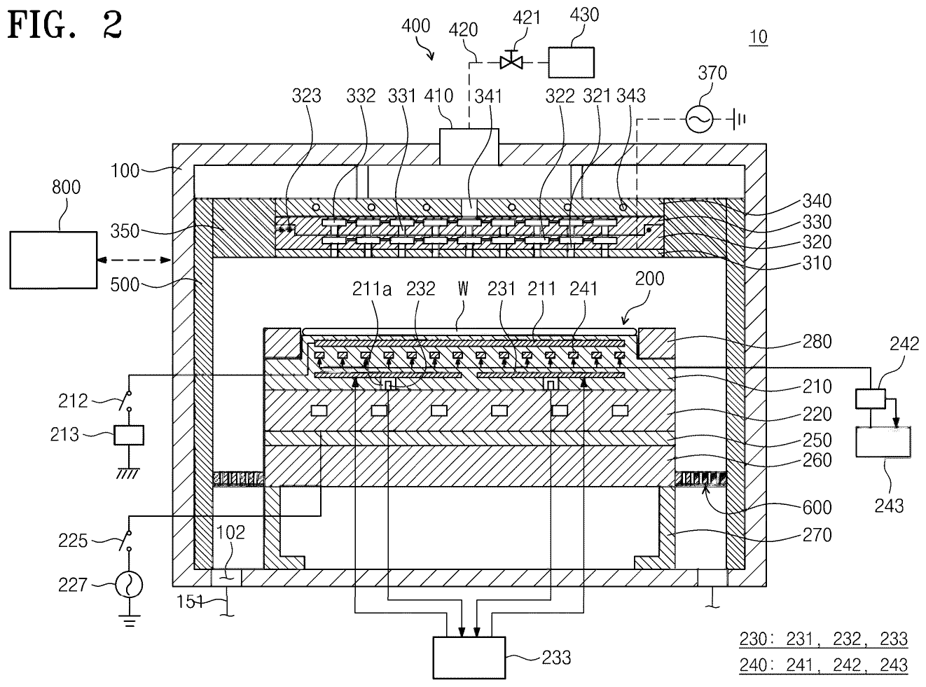

Hereinafter, an embodiment of the inventive concept will be described with reference to FIG. 2 to FIG. 11.

FIG. 2 is a cross-sectional view illustrating a substrate treating apparatus according to an embodiment of the inventive concept.

Referring to FIG. 2, the substrate treating apparatus 10 treats a substrate W using a plasma. The substrate treating apparatus 10 may include a chamber 100, a support unit 200, a shower head unit 300, a gas supply unit 400, a liner 500, a baffle unit 600, and a main controller 800.

The chamber 100 provides a treating space in which a substrate treating process is performed. The chamber 100 has the treating space therein. The chamber 100 is provided in a sealed shape. The chamber 100 is made of a metal material. In an embodiment, the chamber 100 may be made of an aluminum material. The chamber 100 may be grounded. An exhaust hole 102 is formed on a bottom surface of the chamber 100. The exhaust hole 102 is connected to an exhaust line 151. The exhaust line 151 is connected to a pump (not shown). The reaction by-products generated during a process and a gas remaining in an inner space of the chamber 100 may be discharged to the outside through the exhaust line 151. An inside of the chamber 100 is depressurized to a predetermined pressure by an exhaust process.

A heater (not shown) is provided on a wall of the chamber 100. The heater heats the wall of the chamber 100. The heater is electrically connected to a heating power source (not shown). The heater generates a heat by resisting a current applied from the heating power source. A heat generated by the heater is transferred to the inner space. The treating space is maintained at a predetermined temperature by the heat generated by the heater. The heater is provided by a coil-shaped heating wire. One or a plurality of heaters may be provided on the wall of the chamber 100.

The support unit 200 may support the substrate W in the treating space of the chamber 100. The support unit 200 may be an electrostatic chuck which adsorbs the substrate W such as a wafer in an electrostatic manner. In addition, the support unit 200 may adjust a temperature of a supported substrate W. For example, the support unit 200 may increase a temperature of the substrate W to increase a processing efficiency of the substrate W.

The support unit 200 may include a support plate 210, an electrode plate 220, a first heater module 230, a second heater module 240, an insulating plate 250, a bottom plate 260, a support ring 270, and an edge ring 280.

The support plate 210 may have a seating surface on which the substrate W is placed. The support plate 210 may support the substrate W. The support plate 210 may have a substantially disk shape when viewed from above. A top surface of the support plate 210 may have a stepped shape. A height of a center region of the support plate 210 may have a stepped shape to be higher than a height of the edge region. The support plate 210 may be formed of a material including a dielectric. The support plate 210 may be formed of a material including a ceramic.

An electrostatic electrode 211 may be buried in the support plate 210. The electrostatic electrode 211 may generate an electrostatic force to electrostatically suck the substrate W. An electrostatic power source 213 may apply a power to the electrostatic electrode 211. An electrostatic switch 212 may be installed between the electrostatic power source 213 and the electrostatic electrode 211. The electrostatic electrode 211 may selectively chuck the substrate W according to an on/off of the electrostatic switch 212.

In addition, a temperature measurement groove 211a in which a temperature measurement sensor 232 to be described later may be installed may be formed in the support plate 210. The temperature measuring groove 211a may be formed at a bottom portion of the support plate 210. The temperature measurement groove 211a may be formed in a number corresponding to the number of temperature measurement sensors 232. For example, four temperature measurement grooves 211a may be formed.

The electrode plate 220 may be disposed under the support plate 210. A cooling fluid channel may be formed in the electrode plate 220. A refrigerant for preventing a temperature of the electrode plate 220 from excessively increasing may flow through the cooling fluid channel. The refrigerant may be a cooling water or a cooling gas.

A high frequency power may be applied to the electrode plate 220. The RF power source 227 may apply the high frequency power to the electrode plate 220. The RF power source 227 may be a bias power source capable of accelerating ions in a plasma in the treating space in a direction of the substrate W.

The first heater module 230 may heat the support plate 210. The first heater module 230 may adjust the temperature of the substrate W by heating the support plate 210. The first heater module 230 may include a first heater 231, a temperature measurement sensor 232, and a first controller 233.

The first heater 231 may be a resistive heater, such as a polyimide heater, a silicon rubber heater, a mica heater, a metal heater, a ceramic heater, a semiconductor heater, or a carbon heater. The first heater 231 may have a substantially plate shape. The first heater 231 may have a substantially rectangular plate shape. The first heater 231 may have a heating area larger than that of the second heater 241 to be described later. The first heater 231 may be installed at a position lower than the second heater 241 to be described later. The first heater 231 may adjust an overall temperature of the support plate 210. The first heater 231 may be used to increase or decrease the overall temperature of the support plate 210.

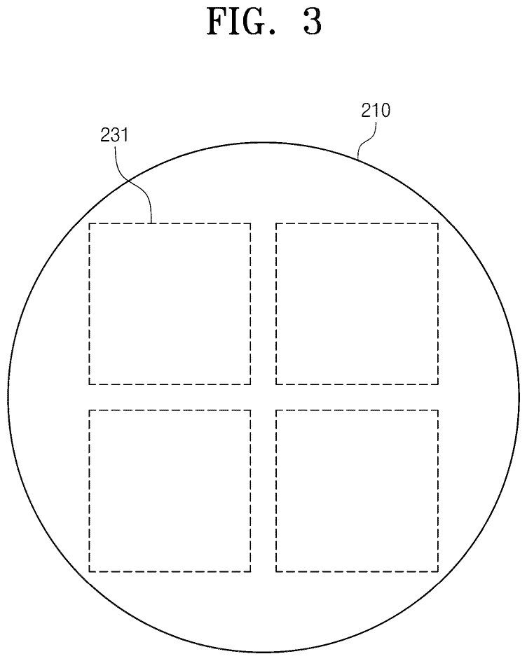

A plurality of first heaters 231 may be provided. For example, as illustrated in FIG. 3, four first heaters 231 may be installed on the support plate 210.

Referring back to FIG. 2, the temperature measurement sensor 232 may measure a temperature of the first heater 231. The temperature measurement sensor 232 may be a fiber optical temperature sensor. The temperature measurement sensor 232 irradiates a light to a bottom surface of the first heater 231, receives a light reflected from the first heater 231, but can measure the temperature of the first heater 231 according to a degree of refraction of the received light. However, a type of the temperature measurement sensor 232 is not limited to this, and may be a contact-type temperature sensor which measures the temperature of the first heater 231 in contact with the first heater 231. The temperature measurement sensor 232 may be provided in a number corresponding to the first heater 231. For example, four temperature measurement sensors 232 may be provided.

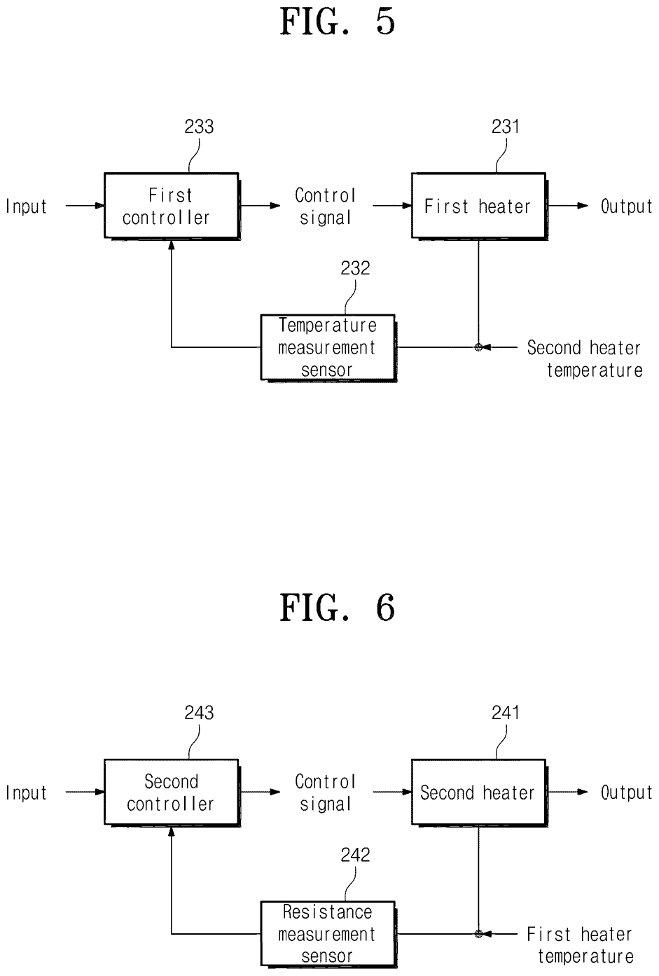

FIG. 5 is an explanatory view schematically illustrating a method of controlling an output of the first heater by a first heater module.

Referring to FIG. 5, the first controller 233 may control an output of the first heater 231. The first controller 233 may include a power source capable of controlling the output of the first heater 231. The first controller 233 may receive an input value from a main controller 800 to be described later. The input value may mean a target temperature of the first heater 231. In addition, the first controller 233 may receive a measurement temperature of the first heater 232 from the temperature measurement sensor 232. The first controller 233 may adjust the output of the first heater 231 so that the measurement temperature of the first heater 231 can reach a target temperature if the target temperature and the measurement temperature are different from each other.

Referring back to FIG. 2, the second heater module 240 may heat the support plate 210. The second heater module 240 may adjust the temperature of the substrate W by heating the support plate 210. The second heater module 240 may include a second heater 241, a resistance measurement sensor 242, and a second controller 433.

The second heater 241 may be a resistive heater, such as a polyimide heater, a silicon rubber heater, a mica heater, a metal heater, a ceramic heater, a semiconductor heater, or a carbon heater. The second heater 241 may have a substantially plate shape. The second heater 241 may have a substantially rectangular plate shape. The second heater 241 may have a heating area smaller than that of the first heater 231 described above. The second heater 241 may be installed at a position higher than that of the first heater 231. The second heater 241 may be used to precisely control a temperature of each region of the substrate W.

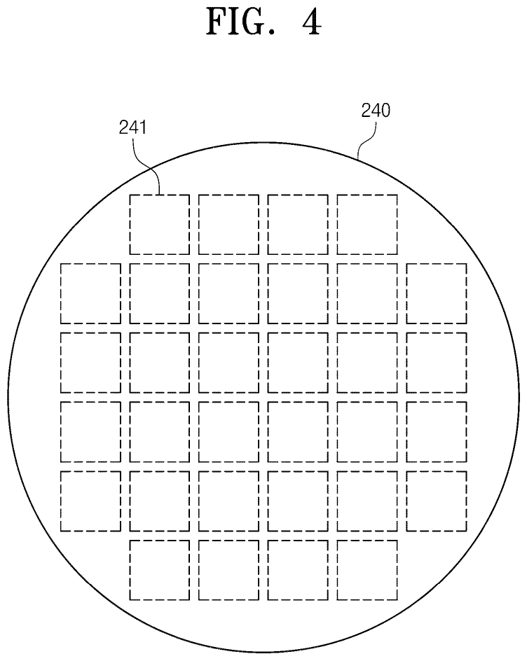

A plurality of second heaters 241 may be provided. For example, as illustrated in FIG. 4, 32 second heaters 241 may be installed on the support plates 210.

Referring back to FIG. 2, a very large number of second heaters 241 are installed on the support plate 210. Therefore, it is structurally very difficult to install the same number of temperature measurement sensors as the second heater 241 in the support unit 200.

Accordingly, the inventive concept includes a resistance measurement sensor 242 for estimating a temperature for each of the second heaters 241. Although FIG. 2 illustrates that one resistance measurement sensor 242 is provided, a plurality of resistance measurement sensors 242 may be provided. The resistance measurement sensor 242 may be provided in a number corresponding to the second heater 241. For example, 32 resistance measurement sensors 242 may be provided. The resistance measurement sensor 242 may include an ammeter and a voltmeter. The resistance measurement sensor 242 can measure a resistance of the second heater 241 through a ratio of a voltage applied to the second heater 241 and a current flowing through the second heater 241. The resistance measurement sensor 242 is sufficient to be installed only on a cable which transmits a power to the second heater 241. Accordingly, the resistance measurement sensor 242 may be installed outside the support plate 210.

FIG. 6 is an explanatory view schematically illustrating a method of controlling an output of the second heater by a second heater module.

Referring to FIG. 6, the second controller 243 may control an output of the second heater 241. The second controller 243 may include a power source capable of controlling the output of the second heater 241. The second controller 243 may receive an input value from a main controller 800 to be described later. The input value may refer to a target temperature of the second heater 241. In addition, the second controller 243 may receive a measurement resistance of the second heater 241 from the resistance measurement sensor 242. The second controller 243 may estimate the temperature of the second heater 241 based on a previously stored compensation factor and the measurement resistance of the second heater 241. The second controller 243 may adjust the output of the second heater 241 so that an estimated temperature of the second heater 241 can reach the target temperature if the target temperature and the estimated temperature are different from each other.

Referring back to FIG. 2, an insulating plate 250 may be provided under the electrode plate 220. The plate 250 may be provided in a circular plate shape. The insulating plate 250 may be provided with an area corresponding to that of the electrode plate 220. The insulating plate 250 may be provided as an insulating plate. In an embodiment, the insulating plate 250 may be provided as a dielectric.

The bottom plate 260 is positioned under the insulating plate 250. The bottom plate 260 may be made of an aluminum material. The bottom plate 260 may be provided in a circular shape when viewed from above. The bottom plate 260 may have an inner space. In the inner space of the bottom plate 260, a lift pin module (not shown) which moves the substrate W from an outer transfer member to the support plate 210 may be positioned.

The support ring 270 is provided under the bottom plate 260. The support ring 270 may be provided in a ring shape and function as a support for supporting the bottom plate 260.

The edge ring 280 is disposed at an edge region of the support unit 200. The edge ring 280 has a ring shape. The edge ring 280 is provided to surround a top portion of the support plate 210. The edge ring 280 may be provided as a focus ring.

The shower head unit 310, 320, 330, 340, 350 is positioned above the support unit 200 in the chamber 100. The shower head unit 310, 320, 330, 340, 350 is positioned to face the support unit 200. The shower head unit 310, 320, 330, 340, 350 includes a shower head 310, a gas spray plate 320, a cover plate 330, a top plate 340, and an insulation ring 350.

The shower head 310 is positioned to be downwardly spaced apart from a top surface of the chamber 100 by a predetermined distance. The shower head 310 is positioned above the support unit 200. A predetermined space is formed between top surfaces of the shower head 310 and the chamber 100. The shower head 310 may be provided in a plate shape having a constant thickness. A bottom surface of the shower head 310 may be anodized to prevent an arc generation by a plasma. A cross section of the shower head 310 may be provided to have a same shape and cross-sectional area as the support unit 200. The shower head 310 includes a plurality of spray holes 311. The spray hole 311 vertically penetrates atop surface and a bottom surface of the shower head 310.

The shower head 310 may be made of a material which generates a compound by reacting with a plasma generated from a gas supplied by the gas supply unit 400. In an embodiment, the shower head 310 may be provided with a material which generates a compound by reacting with an ion having a greatest electronegativity among ions contained in the plasma. For example, the shower head 310 may be made of a material including a silicon. In addition, the compound produced by reacting the shower head 310 with the plasma may be a silicon tetrafluoride.

The shower head 310 may be electrically connected to the top power source 370. The top power source 370 may be provided as a high frequency power source. Unlike this, the shower head 310 may be electrically grounded. A top power source 370 may be a source power source which excites a process gas to a plasma state.

The gas spray plate 320 is positioned on the top surface of the shower head 310. The gas spray plate 320 is positioned to be spaced apart from the top surface of the chamber 100 by a predetermined distance. The gas spray plate 320 may be provided in a plate shape having a constant thickness. A heater 323 is provided in an edge region of the gas spray plate 320. The heater 323 heats the gas spray plate 320.

A diffusion region 322 and a spray hole 321 are provided in the gas spray plate 320. The diffusion region 322 uniformly spreads a gas supplied from above to the spray hole 321. The diffusion region 322 is connected to the spray hole 321 below. The diffusion regions 322 which are adjacent are connected to each other. The spray hole 321 is connected to the diffusion region 322 and penetrates a bottom surface in a vertical direction.

The spray hole 321 is positioned to face the spray hole 311 of the shower head 310. The gas spray plate 320 may include a metal material.

The cover plate 330 is positioned above the gas spray plate 320. The cover plate 330 may be provided in a plate shape having a constant thickness. The diffusion region 332 and the spray hole 331 are provided in the cover plate 330. The diffusion region 332 evenly spreads a gas supplied from above to the spray hole 331. The diffusion region 332 is connected to the spray hole 331 below. The diffusion regions 332 which are adjacent are connected to each other. The spray hole 331 is connected to the diffusion region 332 and penetrates the bottom surface in a vertical direction.

The top plate 340 is positioned above the cover plate 330. The top plate 340 may be provided in a plate shape having a constant thickness. The top plate 340 may be provided in the same size as the cover plate 330. A supply hole 341 is formed in a center of the top plate 340. The supply hole 341 is a hole through which a gas passes. The gas passing through the supply hole 341 is supplied to the diffusion region 332 of the cover plate 330. A cooling fluid channel 343 is formed within the top plate 340. A cooling fluid may be supplied to the cooling fluid channel 343. In an embodiment, the cooling fluid may be provided as a cooling water.

In addition, the shower head 310, the gas spray plate 320, the cover plate 330, and the top plate 340 may be supported by a rod. For example, the shower head 310, the gas spray plate 320, the cover plate 330, and the top plate 340 may be coupled to each other and supported by a rod fixed to the top surface of the top plate 340. In addition, the rod may be coupled to the inside of the chamber 100.

The insulation ring 350 is arranged to surround a circumference of the shower head 310, the gas spray plate 320, the cover plate 330, and the top plate 340. The insulation ring 350 may be provided in a circular ring shape. The insulation ring 350 may be made of a non-metallic material. The insulation ring 350 is positioned to overlap the edge ring 280 when viewed from above. When viewed from above, a surface at which the insulation ring 350 and the shower head 310 contact each other is positioned to overlap a top region of the edge ring 280.

The gas supply unit 400 supplies a gas into the chamber 100. The gas supplied by the gas supply unit 400 may be excited in a plasma state by a plasma source. In addition, the gas supplied by the gas supply unit 400 may be a gas containing a fluorine. For example, the gas supplied by the gas supply unit 400 may be a carbon tetrafluoride.

The gas supply unit 400 includes a gas supply nozzle 410, a gas supply line 420, and a gas storage unit 430. The gas supply nozzle 410 is installed at the center of the top surface of the chamber 100. An injection port is formed on a bottom surface of the gas supply nozzle 410. The injection port supplies a process gas into the chamber 100. The gas supply line 420 connects the gas supply nozzle 410 and the gas storage unit 430. The gas supply line 420 supplies the process gas stored in the gas storage unit 430 to the gas supply nozzle 410. A valve 421 is installed in the gas supply line 420. The valve 421 opens and closes the gas supply line 420 and adjusts a flow rate of the process gas supplied through the gas supply line 420.

The liner 500 prevents an inner wall of the chamber 100 from being damaged during a process. The liner 500 prevents foreign substances generated during the process from being deposited on the inner wall of the chamber 100.

The liner 500 is provided on the inner wall of the chamber 100. The liner 500 has a space in which a top surface and a bottom surface are open. The liner 500 may be provided in a cylindrical shape. The liner 500 may have a radius corresponding to an inner surface of the chamber 100. The liner 500 is provided along the inner surface of the chamber 100. The liner 500 may be made of an aluminum material.

The baffle unit 600 is positioned between an inner sidewall of the chamber 100 and the support unit 200. A baffle is provided in an annular ring shape. A plurality of through holes are formed in the baffle. A gas provided in the chamber 100 passes through the through holes of the baffle and is exhausted to the exhaust hole 102. A gas flow may be controlled according to a shape of the baffle and a shape of the through holes.

The main controller 800 may control the substrate treating apparatus 10. The main controller 800 may control the substrate treating apparatus 10 so that the substrate treating apparatus 10 performs a plasma treatment process on the substrate W.

In addition, the main controller 800 may comprise a process controller consisting of a microprocessor (computer) that executes a control of the substrate treating apparatus 10, a user interface such as a keyboard via which an operator inputs commands to manage the substrate treating apparatus 10, and a display showing the operation situation of the substrate treating apparatus 10, and a memory unit storing a treating recipe, i.e., a control program to execute treating processes of the substrate treating apparatus 10 by controlling the process controller or a program to execute components of the substrate treating apparatus 10 according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

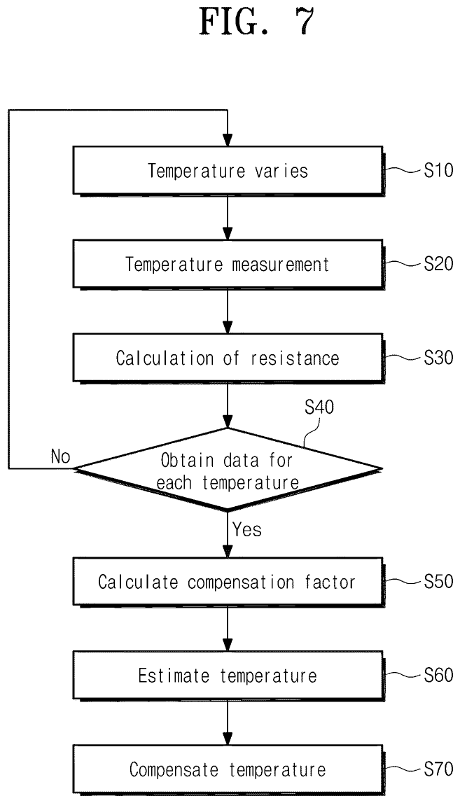

FIG. 7 is a flowchart illustrating a method of controlling a support unit according to an embodiment of the inventive concept.

Referring to FIG. 2 and FIG. 7, in step S10, a temperature of a first heater 231 varies. The temperatures of the first heater 231 vary as T1, T2, T3, etc. The temperature of the first heater 231 may be referred to as a set-point of the first heater 231.

In step S20, the temperature of the first heater 231 is measured. A temperature measurement of the first heater 231 may be performed by the temperature measurement sensor 232. In step S20, the temperature of the first heater 231 in the normal state may be measured. For example, if the temperature of the first heater 231 changes from T1 to T2, a hunting phenomenon may occur until the temperature of the first heater 231 reaches T2. The normal state may mean a stabilized state in which such the hunting phenomenon does not occur. Regarding a determination on the normal state, it may be determined that the normal state is reached if within a change set temperature range of the measurement value of the temperature measurement sensor 232, or if a set time (for example, about one minute) passes after the temperature of the first heater 231 is changed.

In step S30, a resistance of a second heater 241 may be calculated. A resistance calculation of the second heater 241 may be performed by a resistance measurement sensor 242. The resistance calculation of the second heater 241 may be performed after the temperature of the first heater 231 reaches the normal state. In this case, the second heater 241 may be in a state in which a heat is not generated (i.e., a state of not operating).

In step S40, it is determined whether a data securing for each set point of the first heater 231 is completed. If the data securing for each set-point of the first heater 231 is completed, step S50 is performed, and if the data securing for each set-point of the first heater 231 is not completed, step S10 is performed again. During a process of treating the substrate W, the temperature of the first heater 231 may be changed several times. For example, the temperature of the first heater 231 may be changed to T1, T2, and T3 during a treatment process. In this case, the resistance of the second heater 241 is measured when the temperatures of the first heater 231 are T1, T2, and T3. In the treatment process, step S50 is performed if the resistance measurement of the second heater 241 is completed for all set points of the first heater 231.

When step S40 is completed, a collected data for each set-point of the first heater 231 may be as follows.

| Temperature of the first heater. | Resistance of the second heater |
|---|---|
| T1 | R1 |
| T2 | R2 |
| T3 | R3 |

A data collecting may be performed on both the first heater 231 and the second heater 241. For example, in the above-described example, four first heaters 231 and 32 second heaters 241 have been described as examples. Assuming that the temperatures of the first heaters 231 are changed three times to T1, T2, and T3 during a treatment process, a data for each set point of a total of 384 cases may be collected. As described above, the resistance of the second heater 241 according to the temperature change of the first heater 231 is measured because the second heater 241 is affected by the temperature of the first heater 231. In addition, when calculating the compensation factor described below, it is calculated by reflecting the effect of the temperature of the first heater 231, so the temperature of the second heater 241 can be more accurately controlled.

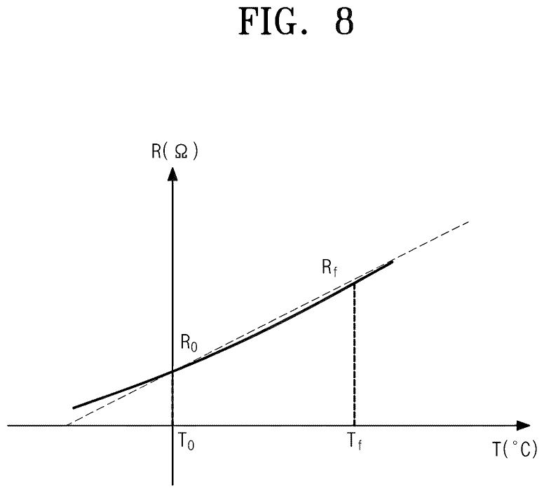

In step S50, a compensation factor is calculated. FIG. 8 is a graph schematically illustrating a resistance change according to a temperature change of a second heater.

Referring to FIG. 2, FIG. 7, and FIG. 8, the temperature of the second heater 241 varies relatively linearly with the resistance value of the second heater 241. The resistance measured at each temperature can be stored in a table form and used as an interpolation, or it can be estimated by the following formula. Hereinafter, the temperature of the second heater 241 estimated by the following equation is defined as the estimated temperature.

$$Tf = T 0 + ( R f - R0 ) / α \qquad [ Equation 1 ]$$

(Tf: Estimated temperature [° C.] of the second heater 241, T0: Initial temperature [° C.] of the second heater 241, Rf: Measured resistance [Ω] of the second heater 241, R0: Initial resistance [Ω] of the second heater 241, α: compensation factor [Ω/° C.])

The initial temperature T0 of the second heater 241 and the initial resistance R0 of the second heater 241 may be an initial measurement temperature (° C.) and resistance (Ω) predetermined based on the prior art. The initial temperature T0 of the second heater 241 and the initial resistance R0 of the second heater 241 may be an initial specification. The initial temperature T0 of the second heater 241 and the initial resistance R0 of the second heater 241 may be an experimental result which may be transmitted from the manufacturer when the second heater 241 is purchased. The values for the initial temperature T0 of the second heater 241 and the initial resistance R0 of the second heater 241 may be stored in the main controller 800 and/or the second controller 243, respectively.

In step S50, the compensation factor for each temperature of the first heater 231 may be calculated, respectively.

A case at which the temperature of the first heater 231 is adjusted to T1 will be described as an example. In the above equation, the initial temperature T0 of the second heater 241 and the initial resistance R0 of the second heater 241 are values known in advance. The measured resistance Rf of the second heater 241 is a measured R1 after adjusting the temperature of the first heater 231 to T1 and reaching a normal state. Ideally, a heat of the first heater 231 is transferred in its entirety to the second heater 241, so that the temperature of the first heater 231 and the temperature of the second heater 241 are the same. Therefore, in the above equation, it is assumed that the estimated temperature Tf of the second heater 241 is T1.

In this case, if the temperature of the first heater 231 is T1, a compensation factor α1 of the second heater 241 is calculated through the following [Equation 2].

$$\begin{matrix}a = ( Rf - R 0 ) / ( Tf - T 0 ) \\ α = T 0 + ( R 1 - R 0 ) / T 1\end{matrix} \qquad [ Equation 2 ]$$

(T1: Speculated temperature [C] of the second heater 241, T0: Initial temperature [° C.] of the second heater 241, Rf: Measured resistance [Ω] of the second heater 241, R0: Initial resistance [Ω] of the second heater 241, α1: compensation factor [Ω/° C.])

When step S50 is completed, the compensation factor for estimating the temperature of the second heater 241 according to a collected temperature of the first heater 231 may be as follows.

TABLE 2

| Temperature of | Resistance of | Compensation |
|---|---|---|
| the first heater | the second heater | factor |
| T1 | R1 | α1 |
| T2 | R2 | α2 |
| T3 | R3 | α3 |

Referring back to FIG. 2 and FIG. 7, in step S60, the temperature of the second heater 241 may be estimated during a process of treating the substrate W. A temperature estimation of the second heater 241 may be performed based on a measured resistance of the second heater 241 measured by the resistance measurement sensor 242. The compensation factor used in calculating the estimated temperature of the second heater 241 may vary according to the temperature of the first heater 231. If the temperature of the first heater 231 is T1, α1 may be used as the compensation factor when calculating the estimated temperature of the second heater 241, if the temperature of the first heater 231 is T2, α2 may be used as the compensation factor when calculating the estimated temperature of the second heater 241, and if the temperature of the first heater 231 is T3, α3 may be used as the compensation factor when calculating the estimated temperature of the second heater 241. The compensation factor may be derived for each of the second heaters 241. Even using the same type of second heater 241, the temperature of the second heater 241 may vary due to a position at which the second heater 241 is installed and a surrounding structure of the second heater 241, and with respect to each of the second heaters 241 of the inventive concept, the compensation factor for each set point of the first heater 231 may be calculated, and the temperature of the second heater 241 may be estimated based on a calculated compensation factor, so the temperature of the second heater 241 may be comparatively precisely estimated.

In step S70, the output of the second heater 241 may be adjusted using the estimated temperature of the second heater 241. For example, if the estimated temperature of the second heater 241 is different from a target set temperature, the second controller 243 can adjust the output of the second heater 241 so that the estimated temperature of the second heater 241 reaches the set temperature.

Since the temperature of the second heater 241 may be accurately estimated, an output control of the second heater 241 may also be accurately performed based on the temperature. In addition, since the temperature of the second heater 241 can be accurately estimated, it is possible to apply the closed-loop system to control the temperature of the second heater 241. If necessary, an open-loop system may be applied to control the temperature of the second heater 241, but the temperature of the second heater 241 may be monitored through the measurement resistance of the second heater 241.

The data obtained in step S40 may be stored in the main controller 800 and/or the second controller 243. The step S50 may be performed in the main controller 800 or the second controller 243. The step S60 may be performed in the main controller 800 or the second controller 243.

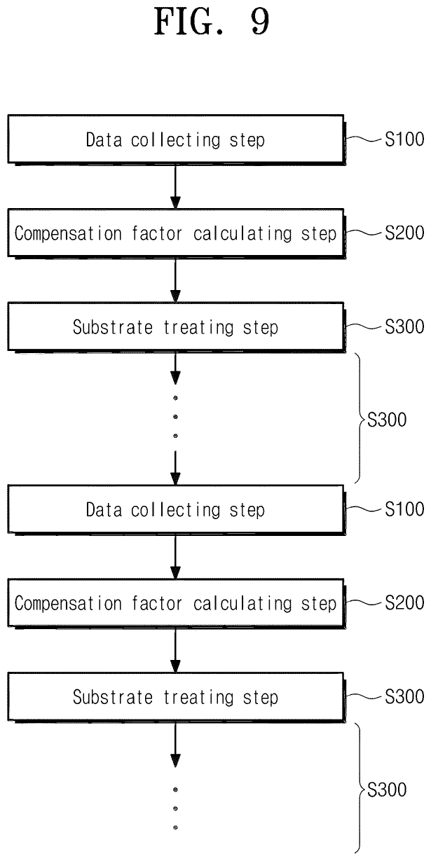

FIG. 9 is a flowchart illustrating a substrate treating method according to an embodiment of the inventive concept. Referring to FIG. 9, a substrate treating method according to an embodiment of the inventive concept may include a data collecting step S100, a compensation factor calculating step S200, and a substrate treating step S300. The data collecting step S100 may correspond to steps S10, S20, S30, and S40 described above. The compensation factor calculating step S200 may correspond to the step S50 described above. The substrate treating step S300 may correspond to steps S60 and S70 described above.

The data collecting step S100 and the compensation factor calculating step S200 may be performed when the substrate treating apparatus 10 is initially set up. After initially setting up the substrate treating apparatus 10, the substrate treating step S300 may be repeatedly performed. Thereafter, the substrate treating apparatus 10 may be driven again for various reasons. For example, a power supply to the substrate treating apparatus 10 may be stopped, an operating of the substrate treating apparatus 10 may be stopped, a maintenance with respect to the substrate treating apparatus 10 may be performed, and then the substrate treating apparatus 10 may be restarted. In this case, as the substrate treating apparatus 10 is maintained, an environment of the second heaters 241 installed in the substrate treating apparatus 10 may be changed. Accordingly, if the substrate treating apparatus 10 is driven again, the data collecting step S100 and the compensation factor calculating step S200 of the inventive concept may be performed before the substrate treating step S300 is performed again.

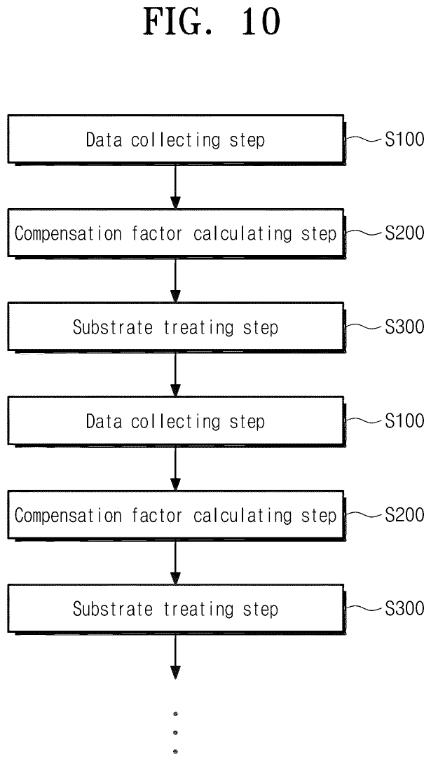

If necessary, the data collecting step S100 and the compensation factor calculating step S200 may be performed before the substrate treating step S300 is performed as shown in FIG. 10. The data collecting step S100 and the compensation factor calculating step S200 may be performed for a time while the substrate W is taken in/out.

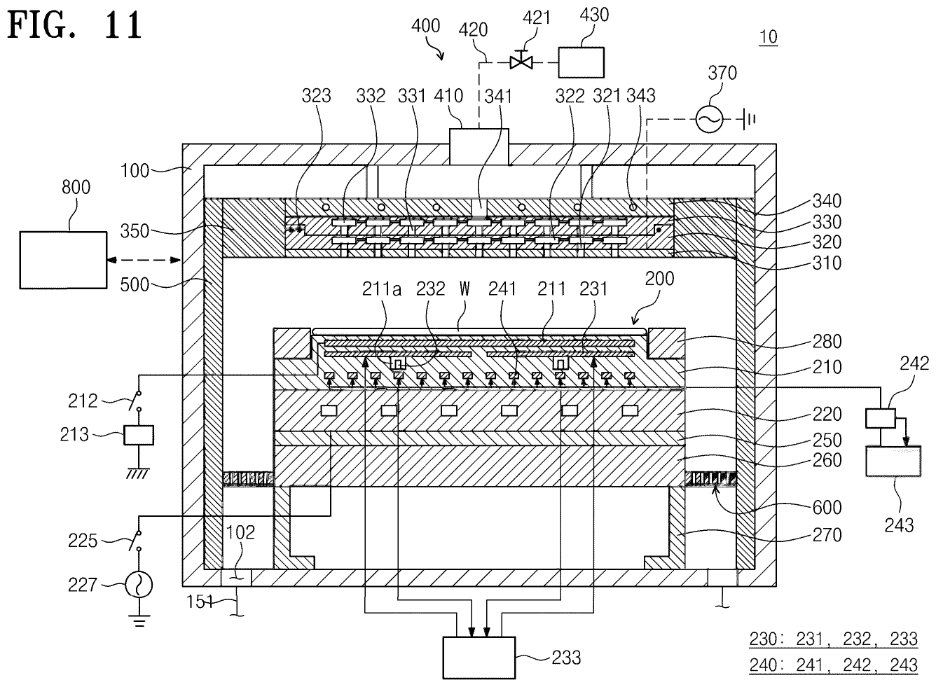

In the above-described example, the second heater 241 is positioned above the first heater 231, but the inventive concept is not limited thereto. For example, as illustrated in FIG. 11, the second heater 241 may be positioned below the first heater 231.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A control method for controlling a support unit including a support plate on which a substrate is placed; a first heater installed on the support plate; and a second heater installed on the support plate at a different height from the first heater, the control method comprising:
determining whether a temperature of the first heater has reached a normal state after the temperature of the first heater varies;
measuring a resistance of the second heater after the temperature of the first heater has reached the normal state; and
calculating a compensation factor for estimating a temperature of the second heater based on the resistance of the second heater which has been measured.

2. The control method of claim 1, wherein the compensation factor is a in the below equation.
$$Tf = T 0 + ( Rf - R 0 ) / α \qquad [ Equation ]$$
(Tf: Estimation temperature of the second heater, T0: Initial temperature of the second heater, Rf: Measurement resistance of the second heater, R0: Initial resistance of the second heater)

3. The control method of claim 2, wherein the temperature of the first heater which has reached the normal state is assumed as the estimation temperature (Tf) of the second heater, and the measurement resistance (Rf) of the second heater is measured after reaching the normal state to calculate the compensation factor.

4. The control method of claim 1, wherein if a change of a measurement value of a temperature measurement sensor which measures the temperature of the first heater is within a set range after the temperature of the first heater varies, or if a set time elapses after the temperature of the first heater varies, it is determined that the normal state has been reached.

5. The control method of claim 1, wherein a first compensation factor is calculated which is the compensation factor corresponding to the first temperature of the first heater after the first heater varies to the first temperature, and
a second compensation factor is calculated which is the compensation factor corresponding to a second temperature of the first heater after the first heater varies to the second temperature which is different from the first temperature.

6. The control method of claim 5, wherein if the temperature of the first heater is adjusted to the first temperature, the resistance of the second heater is measured, and the temperature of the second heater is estimated based on a measured resistance and the first compensation factor, and
if the temperature of the second heater is adjusted to the second temperature, the resistance of the second heater is measured, and the temperature of the second heater is estimated based on a measured resistance and the second compensation factor.

7. The control method of claim 6, wherein the temperature of the second heater is estimated using a measurement resistance of the second heater and the compensation factor, and an output of the second heater is adjusted using the temperature of the temperature of the second heater which is estimated.

8. A substrate treating method using a first heater and a second heater installed at a position which is different from the first heater, the substrate treating method comprising:
collecting a data with respect to a measured resistance of the second heater according to each temperature of the first heater by measuring a resistance of the second heater, after a temperature of the first heater varies, and the temperature of the first heater reaches a normal state;
calculating a compensation factor for estimating a temperature of the second heater according to the measured resistance of the second heater, based on the measurement resistance of the second heater, an initial temperature of the second heater, and an initial resistance of the second heater; and
treating a substrate by estimating the temperature of the second heater using the compensation factor, and controlling an output of the second heater based on the temperature of the second heater which is estimated.

9. The substrate treating method of claim 8, wherein the compensation factor is calculated for each temperature of the first heater which changes at the treating the substrate.

10. The substrate treating method of claim 8, wherein the compensation factor is a in the below equation.
$$Tf = T 0 + ( Rf - R 0 ) / α \qquad [ Equation ]$$
(Tf: Estimation temperature of the second heater, T0: Initial temperature of the second heater, Rf: Measurement resistance of the second heater, R0: Initial resistance of the second heater)

11. The substrate treating method of claim 10, wherein the calculating the compensation factor includes:
assuming the temperature of the first heater which has reached the normal state to be an estimation temperature (Tf) of the second heater;
selecting the measurement resistance of the second heater corresponding to the estimation temperature (Tf) which is assumed collected at the collecting the data; and
calculating the compensation factor (α) by substituting the measurement resistance (Rf) which is selected, the estimation temperature (Tf) which is assumed, the initial temperature (T0) of the second heater which is stored in advance, and the initial resistance (R0) of the second heater which is stored in advance.

12. The substrate treating method of claim 8, wherein at the treating the substrate,
if an estimation temperature of the second heater which is estimated at the treating the substrate is different from a set temperature which is targeted, an output of the second heater is adjusted so the estimation temperature of the second heater reaches the set temperature.

13. The substrate treating method of claim 8, wherein at the collecting the data, it is determined that the normal state is reached if a change of a measurement value of a temperature measurement sensor which measures the temperature of the first heater is within a set range after the temperature of the first heater varies or if a set time elapses after the temperature of the first heater varies.

14. The substrate treating method of claim 8, wherein the collecting the data and the calculating the compensation factor is performed if a substrate treating apparatus which performs the substrate treating method is set up or if the substrate treating apparatus is redriven.

15.-20. (canceled)
